(19) United States
(12) Patent Application Publication
(10) Pub. No.: US 2023/0361255 A1
(43) Pub. Date: Nov. 9, 2023

(54) Optoelectronic Device

(71) Applicant: OSRAM OPTO SEMICONDUCTORS GMBH, Regensburg (DE)

(72) Inventors: Christopher Wiesmann, Barbing (DE); Klemens Ferstl, Regensburg (DE)

(21) Appl. No.: 18/245,414

(22) PCT Filed: Aug. 30, 2021
(86) PCT No.: PCT/EP2021/073915

§ 371 Date: Mar. 15, 2023

(30) Foreign Application Priority Data
Sep. 15, 2020 (DE) 10 2020 124 016.3

(51) Int. Cl. H01L 33/50

(52) U.S. Cl. CPC H01L 33/505

(57) ABSTRACT

An optoelectronic device includes an optoelectronic semiconductor component having an active region configured to generate light and having a light emitting surface through which the generated light is emittable from the semiconductor component, the light emitting surface being arranged on a top surface of the semiconductor component, a converter centered above the light emitting surface and configured to convert the generated light into converted light of at least one other wavelength and an adhesive fixing the converter to the top surface of the semiconductor component, wherein a contour line, projected onto the top surface of the semiconductor component, completely circumvents the converter in a circumferential direction and lies completely within the light emitting surface, wherein the adhesive is arranged between the light emitting surface and the converter and/or in the circumferential direction around the converter.

This patent application is a national phase filing under section 371 of PCT/EP2021/073915, filed Aug. 30, 2021, which claims the priority of German patent application 10 2020 124 016.3, filed Sep. 15, 2020, each of which is incorporated herein by reference in its entirety.

### TECHNICAL FIELD

The present invention relates to an optoelectronic device having an optoelectronic semiconductor component, in particular an LED chip, which has an active region for generating light and a light emitting surface through which the generated light is emitted from the semiconductor component, wherein the light emitting surface is formed on an top surface of the semiconductor component, with a converter which is arranged centered above the light emitting surface and is configured for converting the generated light into converted light having at least one other wavelength, and with an adhesive for fixing the converter to the top surface of the semiconductor component.

### BACKGROUND

In known optoelectronic devices, the converter is fixed to the top surface of the semiconductor component by means of the adhesive. In the process, the adhesive may cover non-emissive areas of the top surface of the semiconductor component. The non-emissive areas of the top surface covered with adhesive absorb incident light, which is in particular light that has been backscattered by the converter. The described effect of absorption results in a loss channel for the generated light, especially when white material surrounds the converter. This reduces the light extraction efficiency of the optoelectronic device.

### SUMMARY

Embodiments provide an optoelectronic device that is improved with respect to its light extraction efficiency.

Embodiments provide an optoelectronic device of the aforementioned type in that—when the converter is arranged on the light emitting surface as intended—a contour line projected onto the top surface of the semiconductor component and completely surrounding the converter in a circumferential direction lies completely within the light emitting surface, and in that the adhesive is arranged between the light emitting surface and the converter and/or in the circumferential direction around the converter in such a way that the adhesive is arranged only on the light emitting surface.

The contour line circumventing the converter, when projected onto the top surface of the semiconductor component, lies entirely within the light emitting surface. Preferably, the contour line corresponds to the outer circumference of the bottom surface of the converter. Therefore, the converter has at least one section in its lower portion whose cross-sectional area parallel to the surface is smaller than the light emitting surface. When the converter is arranged in a centered position above the light emitting surface, this results in an edge region of the light emitting surface which is not covered by the converter, in particular when viewed from above the top surface or the converter. This edge region can be used—in addition to the region below the converter—as a region to which the adhesive can be applied. The use of adhesive outside the edge region is not necessary to fix the converter to the top surface.

In particular, it is provided that no region of the top surface which lies outside the light emitting surface is covered with adhesive. Thus, in an optoelectronic device according to embodiments of the invention, there are no, or at most only slightly, non-emissive areas of the top surface covered with adhesive. Absorption of, in particular, backscattered light by such areas can thus be avoided or at least reduced. The efficiency of the optoelectronic device, in particular with regard to luminous efficiency and brightness, can thus be improved.

The projection of the aforementioned contour line is preferably in a direction perpendicular to the top surface of the semiconductor component. Preferably, the converter is formed as a small platelet which has a flat bottom surface. The bottom surface of the platelet is preferably formed parallel to the top surface of the semiconductor component.

The converter may comprise at least one section extending in a direction perpendicular to the bottom surface of the converter, which provides a continuous contour line projected onto the top surface of the semiconductor component regardless of which cross-sectional area parallel to the bottom surface is considered. Thus, at least in the section, the converter may have a circumferentially extending, continuous circumferential surface. Preferably, the section extends upwardly from the bottom surface of the converter. The section may extend over the entire height of the converter, so that the converter may have a uniform cross-sectional area.

According to a further embodiment of the invention, the light emitting surface may have an outer edge line, in particular an imaginary one, surrounding the light emitting surface in the circumferential direction, and the projected contour line lies entirely within the outer edge line. The outer edge line can be regarded as the outer perimeter of the light emitting surface. No light is emitted from the semiconductor component from regions that lie outside this perimeter. For example, such regions of the top surface of the semiconductor component that lie outside the outer edge line can be metallic regions, for example for the power supply of the semiconductor component.

The projected contour line and the outer edge line can form a circumferential, in particular imaginary, stripe on the light emitting surface, the stripe having a width of 5 μm to 50 μm at any point, preferably a width of 10 μm to 25 μm, further preferably a width of 10 μm to 15 μm. Adhesive may be applied to the strip on the light emitting surface, while outside the strip there is no longer any adhesive on the top surface of the semiconductor component. In particular, adhesive may accumulate on the strip and be pressed outward when the converter is applied to the top surface of the semiconductor component. An overlapping of non-emissive areas of the top surface, which would absorb backscattered light, can thus be avoided.

The light emitting surface can be formed by an epitaxially applied layer of the semiconductor component located on the top surface of the semiconductor component. The light emitting surface can be provided with a coating.

According to one embodiment of the invention, at least one metallic region, preferably at least two metallic regions, may be formed laterally adjacent to the light emitting surface on the top surface of the semiconductor component. The at least one metallic region may be connected to n-doped layers or p-doped layers of the semiconductor component. In particular, at least one metallic region may be provided on the top surface of the semiconductor component, which is connected to at least one n-doped layer of the semiconductor component. Furthermore, at least one other metallic region may be provided on the top surface of the semiconductor component, which is connected to at least one p-doped layer of the semiconductor component. The metallic regions may also be covered by a dielectric layer.

The adhesive may be arranged between the light emitting surface and the bottom surface of the converter and/or circumferentially around the converter in such a way that the adhesive does not cover, not even partially, the at least one metallic region. The light emitting surface and thus the outer edge line may extend immediately adjacent to such metallic regions. With the device according to embodiments of the invention, covering of such metallic regions with adhesive can be avoided or at least reduced. The absorption of back-reflected light at such areas covered with adhesive can therefore be avoided or at least reduced. The light extraction efficiency of the device can thus be improved.

The converter may comprise an upper portion and a lower portion, the lower portion being closer to the light emitting surface than the upper portion, and the upper portion having a larger cross-section than the lower portion when viewed in a plane parallel to the top surface. A circumferential step can thus be formed between the upper portion and the lower portion. Excess adhesive can accumulate in the volume thus recessed, thereby avoiding wetting of non-emissive areas of the top surface of the semiconductor component. The converter can also be formed in one piece.

The upper portion can be centered above the lower portion. This makes it particularly easy to form a uniform, circumferential step between the upper and lower portions, especially if the upper and lower portions are each formed as cuboids.

Preferably, the contour line whose projection onto the top surface of the semiconductor component is entirely within the light emitting surface extends circumferentially around the lower portion. Preferably, the contour line corresponds to the outer periphery of the bottom surface of the converter. Preferably, a contour line projected onto the top surface of the semiconductor component of a contour line circumferentially surrounding the upper portion of the converter is completely outside the projected contour line of the lower portion. Such contour lines can be achieved when both the upper portion and the lower portion are formed as cuboids or cubes, the cuboid or cube forming the upper portion being larger than the cuboid or cube forming the lower portion. For example, the converter may be formed as a cone-shaped or truncated pyramidal-shaped element.

The lower portion of the converter can have conversion material, whereas the upper portion is formed by a, in particular transparent, carrier material and has no conversion material. Alternatively, both the lower portion and the upper portion can have conversion material.

By conversion material is meant a material which absorbs the light generated in the semiconductor component and emits light converted in wavelength with at least one other wavelength. The light generated by the semiconductor component and the converter material may be configured such that the converted light has a desired wavelength or corresponds to white light. The converted light may be emitted from the optoelectronic device to the outside, while the light generated by the semiconductor component is at least normally not emitted to the outside.

The semiconductor component can be, for example, an LED chip or a μLED chip.

### BRIEF DESCRIPTION OF THE DRAWINGS

The invention is described in more detail below by means of exemplary embodiments and with reference to the accompanying figures. They show, schematically in each case,

FIG. 1 a cross-sectional view of a variant of an optoelectronic device;

FIG. 2 a perspective view of a converter of the device of FIG. 1;

FIG. 3 a cross-sectional view of an optoelectronic device;

FIG. 4 a cross-sectional view of a further variant of an optoelectronic device;

FIG. 5 a cross-sectional view of still another variant of an optoelectronic device;

FIG. 6 a cross-sectional view of still another variant of an optoelectronic device;

FIG. 7 a cross-sectional view of still another variant of an optoelectronic device;

FIG. 8 a cross-sectional view of still another variant of an optoelectronic device;

FIG. 9 a cross-sectional view of still another variant of an optoelectronic device;

FIG. 10 a cross-sectional view of still another variant of an optoelectronic device;

FIG. 11 a top view of the top surface of the semiconductor component of the device of FIG. 1; and

FIG. 12 a top view of the bottom surface of the converter of the device of FIG. 1.

### DETAILED DESCRIPTION OF ILLUSTRATIVE EMBODIMENTS

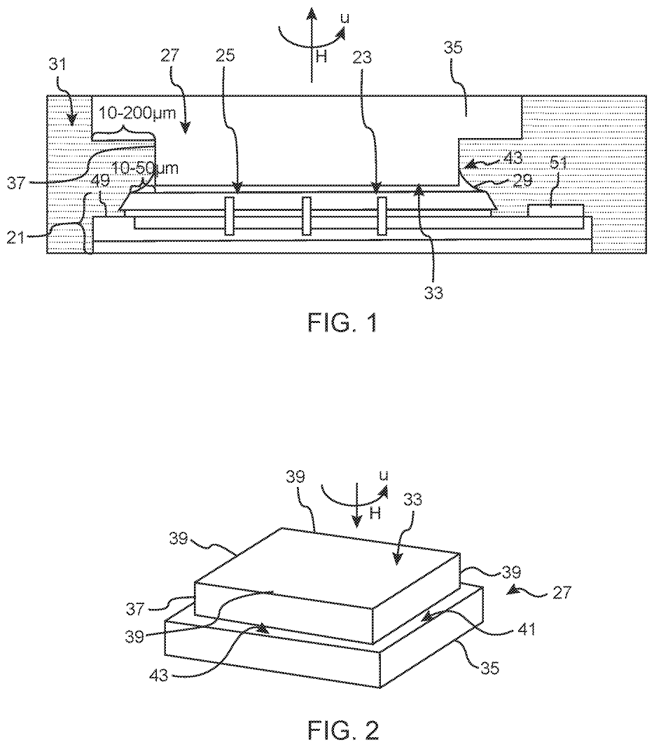

The optoelectronic device shown in cross-section in FIG. 1 comprises an optoelectronic semiconductor component 21, which is in particular an LED chip or a μLED chip. In a manner known per se, the semiconductor component 21 comprises an active region for generating light from electric current. Furthermore, the semiconductor component 21 comprises a light emitting surface 23 provided on the top surface 25 of the semiconductor component 21. The light emitting surface 23 allows the generated light to exit from the interior of the semiconductor component 21.

Seen in height direction H above the top surface 25 a converter 27 is arranged, which is aligned centered to the light emitting surface 23. The converter 27 is configures in a manner known per se for converting the light generated in the semiconductor component 21 into converted light with at least one other wavelength. The height direction H is perpendicular to the top surface 25, to the light emitting surface 23 and to a bottom surface 33 of the converter 27.

The converter 27 is fixed to the top surface 25 of the semiconductor component 21 by means of an adhesive 29.

The mentioned components of the device according to FIG. 1 can be arranged in a housing which is not shown and in particular open at the top. White encapsulation material 31, which can comprise titanium dioxide, for example, can surround the said components, as FIG. 1 shows.

FIG. 2 shows a perspective view of the converter 27, with the bottom surface 33 facing upward. The converter 27 is therefore upside down compared to FIG. 1. Not shown are alternative variants in which the converter is applied to the semiconductor chip in the same way, with a circumferential contour line on the top surface lying within that of the bottom surface. It may also be provided that the top surface and the bottom surface are of the same size.

In the example shown in FIG. 2, the converter 27 comprises an upper portion 35 and a lower portion 37, which can be formed in one piece, for example. Both portions 35 and 37 are each formed in a cuboid shape. The lower portion 37 is located closer to the light emitting surface 23 than the upper portion 35, as shown in FIG. 1. In addition, the upper portion 35 has a larger cross-section than the lower portion 37 when viewed in a plane parallel to the top surface 25. In this case, the upper and lower portions 35, 37 are arranged or formed centered on one another.

The converter 27 has a contour line 39, in particular an imaginary contour line, which completely surrounds the converter 37 in a circumferential direction U lying in a plane perpendicular to the height direction H. The contour line 39 preferably relates to the course of the outer edges on the bottom surface 33 of the converter 27, as shown in FIG. 2.

FIG. 12 schematically shows a top view of the bottom surface 33 of the converter 27, showing the contour line 39 relating to the outer periphery of the lower portion 37. In addition, a lower surface 41 of the upper portion 35 can be seen projecting beyond the contour line 39 on all four sides due to the larger dimensions of the upper portion 35, resulting in a circumferential step 43 between the upper and lower portions 35, 37, as shown in FIG. 2.

FIG. 11 schematically shows a top view of the top surface 25 of the semiconductor component 21. A projection 45 of the contour line 39 onto the light emitting surface 23 is shown. As FIG. 12 shows, when the converter 27 is arranged over the light emitting surface 23 as intended, the projected circumferential contour line 39 is entirely within the light emitting surface 23.

In addition, the adhesive 29 can be arranged between the light emitting surface 23 and the bottom surface 33 of the converter 27 and in the circumferential direction U around the converter 27 in such a way that the adhesive 27 is arranged only on the light emitting surface 23.

In particular, due to the smaller dimensioning of the bottom surface 33 of the converter 27 compared to the light emitting surface 23, a circumferential stripe 47 results on the light emitting surface 23 (cf. FIG. 11), which lies outside the projection 45. In particular, excess adhesive 27 can accumulate on this stripe 47, whereby wetting of regions of the top surface 25 which lie outside the light emitting surface 23 can be avoided or at least reduced. The step 43 above the stripe 47 between the two regions 35, 37 of the converter 27 further permits accumulation of adhesive on the lateral outer surface of the lower portion 37 of the converter 27, as shown in FIG. 1.

Thus, in the optoelectronic device described with reference to FIGS. 1, 2, 11 and 12, the contour line 39 projected onto the top surface 25 of the semiconductor component 21 (cf. projection 45), as viewed in the circumferential direction U, extends entirely within the light emitting surface 23, and the adhesive 29 is arranged between the light emitting surface 23 and the converter 27 and around the converter 27 in the circumferential direction U such that the adhesive 29 covers only the light emitting surface 23.

Regions of the top surface 25 lying immediately outside the light emitting surface 23 thus remain free of adhesive 29. Such regions may be, in particular, metallic regions located laterally adjacent to the light emitting surface 23. FIG. 11 schematically shows two metallic regions 49, 51. In some variants, the metallic region 49 can be in electrical connection with at least one n-doped layer of the semiconductor component 21, and the metallic region 51, which can be designed as a contact area, for example, can be in electrical connection with at least one p-doped layer of the semiconductor component 21. Absorption of back-reflected light at such adhesive-covered metallic regions 49, 51 can be avoided or at least reduced in the device according to FIG. 1, since wetting of such regions with adhesive 29 can preferably be avoided or at least reduced. The light extraction efficiency of the device can therefore be improved.

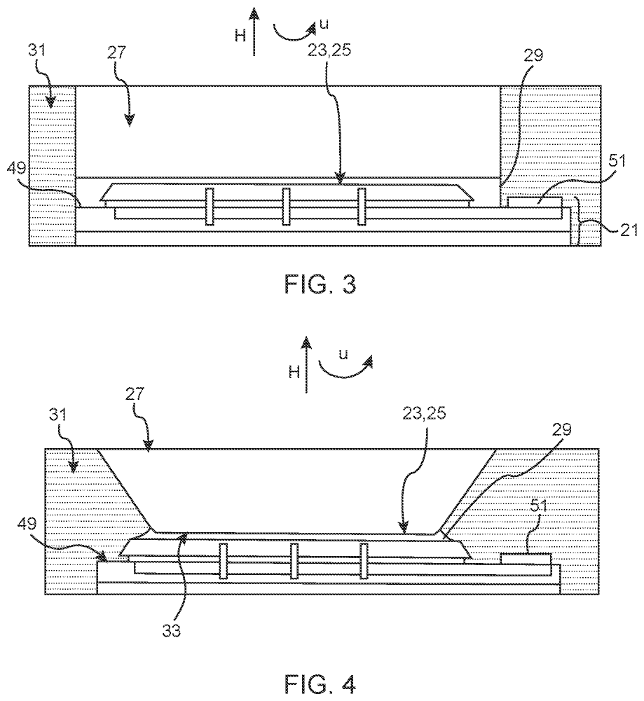

In particular, it has been shown in simulations or experimentally that an improvement in light extraction efficiency of more than five percent can be achieved compared to a device not according to the invention, such as that shown in FIG. 3. In the device according to FIG. 3, corresponding metallic regions 49, 51 can be covered with adhesive 29, since in the device according to FIG. 3 the bottom surface of the converter 27 has a larger surface area than the light emitting surface 23. The adhesive 29 is therefore pressed outwardly when the converter 27 is attached, and in the example shown covers at least the metallic region 49 which is connected to n-doped layers of the semiconductor component 21.

In the device according to FIG. 1, the lower portion 37 of the converter 27 is cuboid-shaped and the lower side 33 thus has a rectangular base surface, as FIG. 2 shows. Correspondingly, the light emitting surface 23 has a rectangular base surface, as FIG. 11 shows.

Preferably, the length and width of the bottom surface 33 is smaller than the corresponding length and width of the light emitting surface 23 by 10 μm to 50 μm, more preferably 20 μm to 30 μm.

The length and width of the lower surface 41 of the upper portion 35, which is also rectangular, is in each case preferably 10 μm to 200 μm, more preferably 30 μm to 100 μm, greater than the corresponding length and width of the bottom surface 33 in some variants, particularly those trimmed for efficiency.

The configuration of the converter 27 with a cuboidal upper and lower portion 35, 37 is to be seen only as an example. Other shapes of the converter 27 are also possible. Similarly, a rectangular shape of the bottom surface 33 of the converter 27 and a rectangular light emitting surface 23 are to be considered as examples only.

The variants of FIGS. 4 to 10 are explained in particular in comparison with the variant according to FIG. 1, with reference being made to similarities between the variants only in exceptional cases and the differences explained in particular.

In the variant of FIG. 4, the converter 27 is formed in one piece as a truncated pyramid. The bottom surface 33 has a smaller area than the light emitting surface 23. A contour line projected onto the top surface 25 of the semiconductor component 21 (cf. contour line 45 in FIG. 1i), which runs completely around the bottom surface 33 of the converter 27 in a circumferential direction U, thus lies completely within the light emitting surface 23. A free stripe 47 of the light emitting surface 23 can thus be covered by, in particular, excess adhesive 29, whereby a covering of regions of the top surface 25 lying outside the light emitting surface 23 with adhesive can be avoided or at least reduced. The same applies accordingly to the figures explained below.

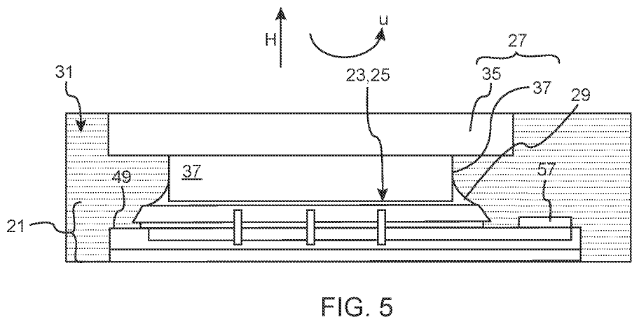

In the variant of FIG. 5, the upper portion 35 of the converter 27 is formed as a transparent carrier, for example of glass. Only the lower portion 37 therefore has material for converting light, while the upper portion 35 is not configured for converting light. The upper portion 35 may perform a protective function, for example against moisture.

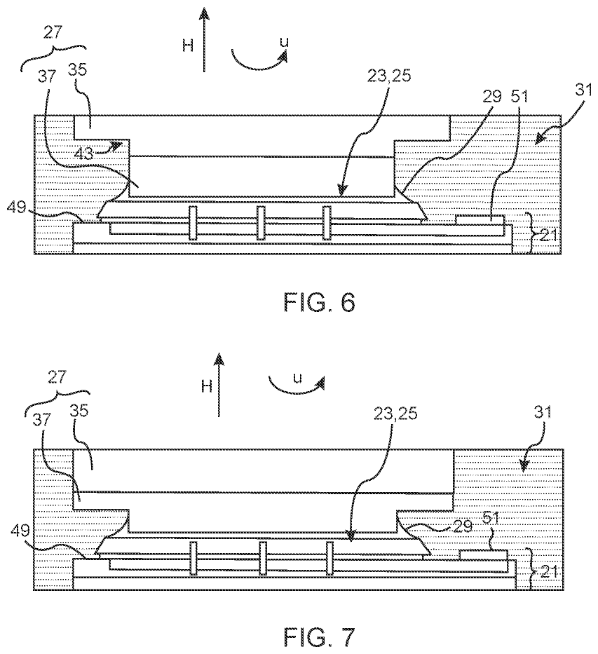

In the variant of FIG. 6, the upper portion 35 of the converter 27 is again formed as a transparent support, for example of glass. In addition, the circumferential step 43 (cf. FIG. 2) is implemented in the upper portion 35. A section of the upper portion 35 adjacent to the lower portion 37 therefore has the same cross-section as the lower portion 37. In contrast, an upper section of the upper portion 35 has a larger cross-section, whereby the step 43 is realized in the upper portion 35.

In the variant of FIG. 7, the upper portion 35 of the converter 27 is designed as a transparent support, for example made of glass. In addition, the circumferential step 43 (cf. FIG. 2) is implemented in the lower portion 37. An upper portion of the lower portion 37 adjacent to the upper portion 35 therefore has the same cross-section as the upper portion 35.

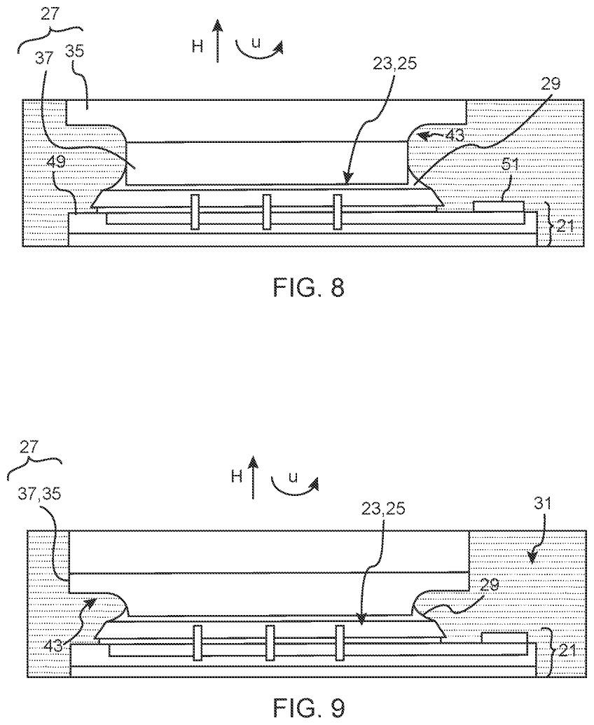

In the variants of FIGS. 8 and 9, the upper portion 35 of the converter 27 is again formed as a transparent support, for example of glass. Fillets in the area of the step 43 may be created or generated by the manufacturing process.

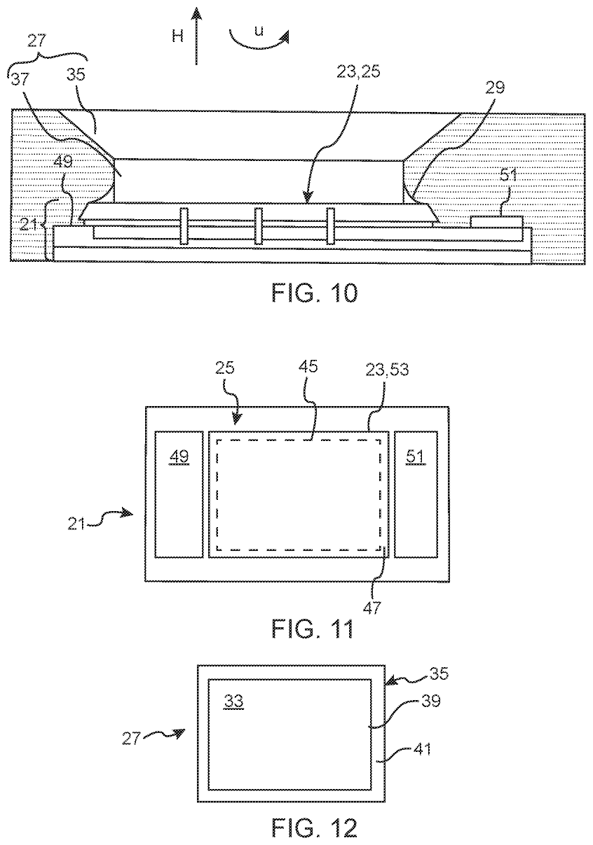

In the variant of FIG. 10, the upper portion 35 of the converter 27 is formed as a transparent carrier, for example of glass. The carrier has a truncated pyramid shape. The side of the upper portion 35 adjacent to the lower portion 37 has the same cross-section as the lower portion 37. This cross-section increases continuously along the height direction H up to the top surface of the converter 27.

The step 43 can be made by sawing through the lower portion 37 from the lower side 33 in the height direction H, using a relatively wide sawing means. Further sawing through the converter 27 can be done with a narrower sawing means. Depending on the sawing depth of the wider sawing means, the step 43 can be realized in the transition region between the upper and lower portions 35, 37, in the upper portion 35 or in the lower portion 37.

Instead of a converter, an optical element can also be provided. For example, there may be components in which a transparent window is glued onto a chip.

In this respect, the invention also relates to an optoelectronic device comprising:
an optoelectronic semiconductor component, in particular an LED chip, having an active region for generating light and having a light emitting surface through which the generated light is emitted from the semiconductor component, the light emitting surface being formed on an top surface of the semiconductor component,
an optical element centered above the light emitting surface, and
an adhesive for fixing the optical element,
wherein a contour line projected onto the top surface of the semiconductor component and completely surrounding the optical element in a circumferential direction is located entirely within the light emitting surface, and
wherein the adhesive is disposed between the light emitting surface and the optical element and/or circumferentially around the optical element such that the adhesive is disposed only on the light emitting surface.

Features mentioned above also apply in connection with variants in which an optical element is present instead of a converter.

Although the invention has been illustrated and described in detail by means of the preferred embodiment examples, the present invention is not restricted by the disclosed examples and other variations may be derived by the skilled person without exceeding the scope of protection of the invention.

1.-13. (canceled)

14. An optoelectronic device comprising:
an optoelectronic semiconductor component having an active region configured to generate light and having a light emitting surface through which the generated light is emittable from the semiconductor component, the light emitting surface being arranged on a top surface of the semiconductor component;
a converter centered above the light emitting surface and configured to convert the generated light into converted light of at least one other wavelength; and
an adhesive fixing the converter to the top surface of the semiconductor component,
wherein a contour line, projected onto the top surface of the semiconductor component, completely circumvents the converter in a circumferential direction and lies completely within the light emitting surface,
wherein the adhesive is arranged between the light emitting surface and the converter and/or in the circumferential direction around the converter in such a way that the adhesive is arranged only on the light emitting surface, and
wherein at least one metallic region is arranged laterally next to the light emitting surface on the top surface of the semiconductor component.

15. The optoelectronic device according to claim 14, wherein the contour line corresponds to an outer circumference of a bottom surface of the converter.

16. The optoelectronic device according to claim 14, wherein the light emitting surface comprises a peripheral outer edge line surrounding the light emitting surface in the circumferential direction, and wherein the projected contour line lies completely within the outer edge line.

17. The optoelectronic device according to claim 16, wherein the projected contour line and the outer edge line form a circumferential stripe on the light emitting surface, and wherein the stripe has at each location a width between 5 μm and 50 μm, inclusive.

18. The optoelectronic device according to claim 16, wherein the projected contour line and the outer edge line form a circumferential stripe on the light emitting surface, and wherein the stripe has at each location a width between 10 μm and 15 μm, inclusive.

19. The optoelectronic device according to claim 14,
wherein the light emitting surface is formed by an epitaxial layer of the semiconductor component lying on the top surface, and/or
wherein a white material surrounds the converter.

20. The optoelectronic device according to claim 14, wherein the adhesive is arranged between the light emitting surface and the converter and/or in the circumferential direction around the converter such that the adhesive does not cover the at least one metallic region.

21. The optoelectronic device according to claim 20, wherein the adhesive does not even partially cover the at least one metallic region.

22. The optoelectronic device according to claim 14, wherein the converter comprises an upper portion and a lower portion, the lower portion being closer to the light emitting surface than the upper portion, and wherein the upper portion comprises a larger cross-section than the lower portion when viewed in a plane parallel to the top surface.

23. The optoelectronic device according to claim 22, wherein the contour line extends in the circumferential direction around the lower portion.

24. The optoelectronic device according to claim 22, wherein a contour line projected on the top surface of the semiconductor component and surrounding the upper portion of the converter in the circumferential direction is completely outside a projected contour line of the lower portion.

25. The optoelectronic device according to claim 22, wherein the lower portion comprises a converter material while the upper portion comprises a transparent carrier material.

26. The optoelectronic device according to claim 14, wherein the converter is:
a cuboid element,
a component with an upper portion and a lower portion, wherein both portions are each cuboid elements, wherein the upper portion comprises a square or rectangular first side on which a square or rectangular second side of the lower portion is arranged, and wherein the first side has a larger area than the second side, or
at least partially a truncated conical or pyramidal element.

27. The optoelectronic device according to claim 14, wherein the metallic region is covered by a dielectric material.

28. The optoelectronic device according to claim 27, wherein the adhesive is arranged between the light emitting surface and the converter and/or in the circumferential direction around the converter such that the adhesive does not cover the dielectric material.

29. The optoelectronic device according to claim 28, wherein the adhesive does not even partially cover the dielectric material.

30. The optoelectronic device according to claim 14, wherein the optoelectronic semiconductor component is an LED chip.

31. An optoelectronic device comprising:
an optoelectronic semiconductor component having an active region configured to generate light and having a light emitting surface through which the generated light is emittable from the semiconductor component, the light emitting surface being arranged on an top surface of the semiconductor component;
a window centered above the light emitting surface; and
an adhesive fixing the window to the top surface of the semiconductor component,
wherein a contour line, projected onto the top surface of the semiconductor component, completely circumvents the window in a circumferential direction and lies completely within the light emitting surface, and
wherein the adhesive is arranged between the light emitting surface and the window and/or in the circumferential direction around the window such that the adhesive is arranged only on the light emitting surface.
